(19) United States
(12) Patent Application Publication
(10) Pub. No.: US 2026/0318954 A1
(43) Pub. Date: Oct. 15, 2026

(54) CURRENT MEASURING RESISTOR

(71) Applicant: ISABELLENHUETTE HEUSLER GMBH & CO. KG, Dillenburg (DE)

(72) Inventors: Jens HARTMANN, Eschenburg (DE); Andreas LAUFER, Biebertal (DE); Benedikt KRAMM, Wettenberg (DE); Jan MARIEN, Herborn (DE)

(21) Appl. No.: 18/577,927

(22) PCT Filed: Jul. 20, 2022
(86) PCT No.: PCT/EP2022/070407

§ 371 Date: Jan. 9, 2024

(30) Foreign Application Priority Data
Aug. 31, 2021 (DE) 102021122491.8

(51) Int. Cl. G01R 1/20; H01C 1/014; H01C 3/06

(52) U.S. Cl. CPC G01R 1/203; H01C 3/06; H01C 1/014

(57) ABSTRACT

The invention relates to a current measuring resistor (1) for measuring an electric current, said resistor comprising: a first connection part (2) for conducting the current to be measured into the current measuring resistor (1); a second connection part (3) for conducting the current to be measured out of the current measuring resistor (1); and a resistance element (4) made of a resistive material, the resistance element (4) being located between the two connection parts (2, 3) in the current flow direction so that the electric current to be measured flows through the resistance element (4) during a current measurement. The invention provides a flexible deformation element (4) for making it possible to deform the current measuring resistor (1) in a non-destructive and reversible manner, in particular for compensating for a change in distance or a change in alignment between the connection parts (2, 3) of the current measuring resistor (1), the deformation element (4) being located between the two connection parts (2, 3) in the current flow direction so that the electric current to be measured flows through the deformation element (4) during the current measurement.

### TECHNICAL FIELD OF THE INVENTION

The invention relates to a current measuring resistor for measuring an electric current. Furthermore, the invention relates to a printed circuit board arrangement comprising a printed circuit board and such a current measuring resistor.

### BACKGROUND OF THE INVENTION

Low-ohmic current measuring resistors (“shunts”) are known from the prior art (e.g. EP 0 605 800 A1), which enable current measurement according to the four-wire technique. Here, the electric current to be measured is conducted through the low-ohmic current measuring resistor, whereby the voltage drop across the current measuring resistor is measured. In accordance with Ohm's law, the measured voltage drop is then a measure of the electric current flowing through the low-ohmic current measuring resistor.

Such low-ohmic current measuring resistors have two connection parts made of a conductor material (e.g. copper) to introduce the electric current into the current measuring resistor and to conduct it away from the current measuring resistor. In the direction of current flow between the two connection parts there is a low-ohmic resistor element made of a resistor material (e.g. Manganin®), so that the electric current to be measured flows through the resistor element. When measuring the current, the voltage drop across the resistor element is measured. These known current measuring resistors can, for example, be screwed to busbars in order to supply or remove the current to be measured.

The fact that the known current measuring resistors are rigid can be problematic here, so that the connection points of the current measuring resistor do not allow any relative movement to each other. This is also problematic, for example, if the distance between the connection points changes due to thermal expansion or vibration.

### DESCRIPTION OF THE INVENTION

The invention is therefore based on the task of creating a correspondingly improved current measuring resistor.

This task is solved by a current measuring resistor according to the main claim.

The current measuring resistor according to the invention has, first of all, in accordance with the known current measuring resistor described at the beginning, a first connection part which preferably consists of a conductor material (e.g. copper, copper alloy, aluminum, aluminum alloy) and serves to introduce the electrical current to be measured into the current measuring resistor.

Furthermore, the current measuring resistor according to the invention has a second connection part, which preferably consists of a conductor material (e.g. copper, copper alloy, aluminum, aluminum alloy), in order to lead the electric current to be measured out of the current measuring resistor again.

In the direction of current flow between the two connection parts, a resistor element is arranged, which consists of a resistor material (e.g. Manganin®), so that the electric current to be measured flows through the resistor element during a current measurement. This enables current measurement according to the four-wire technique in a known manner, in that the voltage drop across the resistor element is measured during the current measurement, so that the measured voltage drop is a measure of the electric current flowing through the current measuring resistor in accordance with Ohm's law.

It should be mentioned here that the two connection parts do not necessarily have to consist of the same conductor material. Rather, it is also possible within the scope of the invention that the two connection parts consist of different conductor materials, for example of copper or a copper alloy on the one hand and of aluminum or an aluminum alloy on the other hand.

Furthermore, within the scope of the invention, there is also the possibility that the two connection parts and the resistor element all consist of the same resistor material, so that the current measuring resistor can be in one piece.

Preferably, however, the current measuring resistor according to the invention comprises three parts (resistor element and two connection parts), the two connection parts being made of a conductor material, while the resistor element is made of a resistor material.

Compared to the prior art, the current measuring resistor according to the invention is characterized by at least one flexible deformation element, which enables the current measuring resistor to be deformed non-destructively and reversibly. This makes it possible, for example, to change the distance between the connection parts of the current measuring resistor or to angle the connection parts relative to each other, for example, when the current measuring resistor is twisted and/or bent. In this case, the deformation element is arranged between the two connection parts in the direction of current flow, so that the electric current to be measured flows through the deformation element during the current measurement.

It should be mentioned here that the current measuring resistor according to the invention can have several deformation elements, which can be arranged parallel to each other, for example. For example, several flexible foils can be arranged on top of each other as deformation elements and form a stack.

In a preferred embodiment of the invention, the deformation element is formed by the resistor element, i.e. the deformation element and the resistor element are identical in this case. However, it is also possible alternatively that the deformation element on the one hand and the resistor element on the other hand are separate components which are arranged one behind the other in the direction of current flow.

Furthermore, it should be mentioned that the deformation element can optionally be elastically or plastically deformable.

However, the deformation element should allow a non-destructive change in length of the current measuring resistor of at least 10%, 20%, 30%, 50%, 80% or 100%, where the change in length can be related to the current flow direction or to the shortest distance between the contacting points for the introduction or discharge of the current.

Furthermore, it should be mentioned that the deformation element preferably enables a non-destructive bending of the connection parts relative to each other of at least 10°, 20°, 40°, 80°, 90°, 100°, 135° 160° or 180°, wherein the bending angle in the case of plate-shaped connection parts is related to the plate plane of the connection parts.

Furthermore, the deformation element can allow a non-destructive rotation of the connection parts relative to each other with a rotation angle of 10°, 20°, 40°, 80° or even 90°, the rotation angle preferably being related to the current flow direction in the current measuring resistor.

However, the deformation element may allow for various types of deformation, such as combined bending and twisting.

For example, the deformation element may be a foil or foil stack, a tape or tape stack, or a strand or strand bundle, to name a few examples.

Furthermore, there is also the possibility that the deformation element is a braid. Alternatively, it is also possible that the deformation element is formed as a stack, bundle or braid, in particular with a connection to the connection parts by pressing, welding, riveting or crimping.

In one embodiment according to the invention, the deformation element is not connected directly to the actual connection parts, but indirectly via mechanical connection elements. The connection elements are thus connected on the one hand to the connection parts and on the other hand to the deformation element. The actual connection parts can enclose, cover or sheathe the connection elements so that the connection area also forms an electrical contact region. Alternatively, it is possible for the connection parts to be spatially separated from the connection elements, so that the connecting area is separate from the contact region.

With regard to the mechanical connection between the deformation element on the one hand and the connection parts or the connection elements on the other, there are many possibilities within the scope of the invention. For example, this connection can be a press connection, a welded connection, a riveted connection or a crimp connection, to name just a few examples.

It has already been briefly mentioned above that the current measuring resistor according to the invention enables current measurement according to the four-wire technique. For this purpose, the current measuring resistor can have integrated voltage taps which are attached to the first or second connection part and/or alternatively to the resistor element. The voltage drop between the two voltage taps then forms a measure of the electric current flowing through the current sensing resistor in accordance with Ohm's law.

For example, the voltage taps on the connection parts or the resistor element can each be formed by a pin (contact pin). These pins can, for example, be pressed into holes in the connection parts or in the resistor element or welded or soldered onto the connection parts or onto the resistor element. It should be mentioned here that the pins of the voltage taps can be made of the conductor material of the connection parts or of the resistor material of the resistor element. It should also be mentioned that the pins of the voltage taps can be provided with a coating, for example with a coating of tin or silver.

In order to influence the current flow in the current measuring resistor, current shadows can be provided in the two connection parts in the form of an incision in each case, the incisions preferably extending over the entire thickness of the connection parts.

It should be mentioned here that the current shadows in the connection parts preferably surround the voltage taps at least partially. For example, the current shadows can be L-shaped, U-shaped, C-shaped, V-shaped, straight or arc-shaped (e.g. circular arc-shaped), to name just a few possible shapes.

In general, it should be mentioned that the current shadows in the connection parts can have the same shape. Alternatively, however, it is also possible for the current shadows in the two connection parts to have different shapes.

Furthermore, it should be noted that the current shadows in the two connection parts can optionally have the same or a different length, the length being measured along the incision.

With regard to the spatial arrangement of the current shadows in the current measuring resistor, various possibilities also exist within the scope of the invention. In a preferred embodiment of the invention, the current shadows start from the edge of the current measuring resistor and extend inwards transversely to the direction of current flow. However, alternatively, it is also possible that the current shadows are spaced from the edge of the current sensing resistor.

Furthermore, it should also be mentioned that the current shadows can optionally have the same distance or different distances from the lateral edge of the current measuring resistor. The lateral edge of the current measuring resistor is here the edge of the current measuring resistor that runs parallel to the main current flow direction in the current measuring resistor.

In addition, a current shadow in the form of an incision can also be arranged in the resistor element in order to influence the current flow in the resistor element. Here, too, the current shadow in the resistor element can start from the lateral edge of the resistor element or be spaced apart from the lateral edges of the current measuring resistor. However, it should be mentioned here that the current shadow in the resistor element is preferably arranged centrally between the two connection parts.

Furthermore, it is possible within the scope of the invention that a trim cut is made in the resistor element or in the connection elements in order to adjust the resistance value of the current measuring resistor. For example, this trim cut can be introduced by stamping, milling, drilling, grinding or lasering.

With regard to the spatial arrangement of the trim cut in the current measuring resistor, various possibilities exist within the scope of the invention. For example, the trim cut can be arranged at the edge of the current sensing resistor or spaced from the edges in the surface of the current sensing resistor.

In the case of a stack, the trim cut and current shadows may be located in one plane of the stack, in multiple planes of the stack, or in all planes of the stack.

It has already been mentioned above that the voltage taps on the current measuring resistor can be formed as pins (contact pins). Alternatively, however, it is also possible that the voltage taps are each formed by contact pads on the connection parts or the resistor element.

Furthermore, it is also possible that the voltage taps are formed by mating contact surfaces which are in contact with the connection parts or the resistor element, whereby these mating contact surfaces are optionally located on a printed circuit board.

It has already been mentioned above that the conductor material of the connection parts can be copper, a copper alloy, aluminum or an aluminum alloy. However, the invention is not limited to these exemplary materials with regard to the conductor material of the connection parts.

For example, the resistive material of the resistor element may be a copper alloy, such as a copper-manganese-tin alloy (e.g. CuMn12Ni2 or CuMn7Sn2,3). Alternatively, the resistor material may be a copper-manganese-nickel alloy (e.g., Cu84Ni4Mn12 or Cu65Mn25Ni10). Furthermore, it is also possible that the resistor material is a copper-chromium alloy or a nickel alloy, such as nickel-chromium (e.g. NiCr20AlSi or CuMnNi).

In general, it should be mentioned that the conductor material of the connection parts should have a lower specific electrical resistance than the resistor material of the resistor element, i.e. the connection parts should have a lower resistance than the resistor element.

Therefore, the resistive material of the resistor element preferably has a low resistivity, which is preferably smaller than 2·10⁻⁴ Ω·m, 2·10⁻⁵ Ω·m or 2·10⁻⁶ Ω·m. However, the resistivity of the resistive material of the resistor element is preferably greater than 2·10⁻⁶ Ω·m or 2·10⁻⁷.

The conductor material of the connection parts, on the other hand, preferably has a specific electrical resistance that is less than 10⁻⁶ Ω·m or 10⁻⁷ Ω·m.

With regard to temperature stability, it should be mentioned that the resistive material of the resistor element preferably has a temperature coefficient of electrical resistance that is less than 50 ppm/K in the temperature range from T1 equal to −20 °C to +140 °C relative to a reference temperature TRef=20 °C.

Furthermore, it should also be mentioned that the connection parts can be coated with a coating, which can be made of nickel, a nickel alloy, tin or a tin alloy, to name just a few examples.

Furthermore, it is to be mentioned in general that the connection parts and/or the resistor element may be plate-shaped, whereby the connection parts and the resistor element may optionally be flat or bent.

In general, it should also be mentioned that the electrical resistance value of the current measuring resistor is preferably at most 10 mΩ, 1 mΩ, 100μΩ or 10μΩ.

In addition to the current measuring resistor according to the invention described above, the invention also comprises a measuring arrangement with a current measuring resistor according to the invention and a contacting partner (e.g. printed circuit board, stamped grid, plug, pin), wherein at least one of the connection parts of the current measuring resistor is electrically and mechanically connected to the contacting partner.

Other advantageous further embodiments of the invention are indicated in the dependent claims or are explained in more detail below together with the description of the preferred embodiments of the invention with reference to the figures.

### BRIEF DESCRIPTION OF THE DRAWINGS

FIG. 1 shows a schematic representation of a current measuring resistor according to the invention with a flexible connection element.

FIG. 2 shows a variation of FIG. 1.

FIG. 3 shows a variation of FIGS. 1 and 2 with two separate mechanical connection elements between the deformation element and the connection parts.

FIG. 4 shows a variation of FIGS. 1-3 with voltage taps in the form of pins.

FIG. 5 shows a schematic representation of a printed circuit board arrangement according to the invention with a current measuring resistor according to the invention.

FIGS. 6-16 show various schematic representations of current measuring resistors according to the invention with so-called current shadows in the connection parts or in the resistor element.

FIG. 17 shows a schematic representation to illustrate the possible bending of the current measuring resistor.

FIG. 18 shows a schematic diagram to illustrate the possible twisting of the current measuring resistor.

### DETAILED DESCRIPTION OF THE DRAWINGS

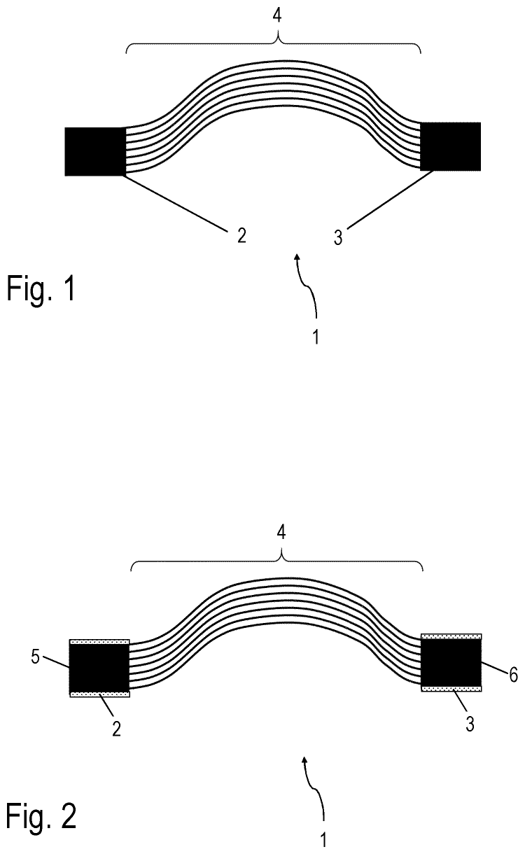

FIG. 1 shows a schematic representation of a current measuring resistor 1 according to the invention, which enables current measurement according to the four-wire technique, as is known per se from the prior art.

For this purpose, the current measuring resistor 1 in this embodiment has two plate-shaped connection parts 2, 3, which serve to introduce the electric current to be measured into the current measuring resistor 1 and to lead it out of the current measuring resistor 1, respectively. The connection parts 2, 3 therefore consist of a low-ohmic conductor material, such as copper, a copper alloy, aluminum or an aluminum alloy.

In the direction of current flow between the two connection parts 2, 3, there is a resistor element 4 made of a resistance alloy, such as Manganin®, to name just one example.

During a measurement, the electric current to be measured flows between the connection parts 2, 3 through the resistor element 4. To measure the current, the voltage drop across the resistor element 4 is measured, whereby the measured voltage drop is a measure of the electric current flowing through the current measuring resistor 1 in accordance with Ohm's law.

A special feature of the current measuring resistor 1 according to the invention is that the resistor element 4 is not rigid, as is now the case with the known current measuring resistors described at the beginning. Rather, the resistor element 4 is flexible here and thus forms a deformation element which makes it possible to change the position of the connection parts 2, 3 relative to one another. The resistor element 4, which is designed as a deformation element, thus enables mechanical decoupling of the connection parts 2, 3 relative to one another.

In the drawing, the resistor element 4 is shown only schematically to indicate that the resistor element 4 is flexibly deformable. For example, the resistor element 4 can be formed as a foil or as a braid to enable the desired deformability.

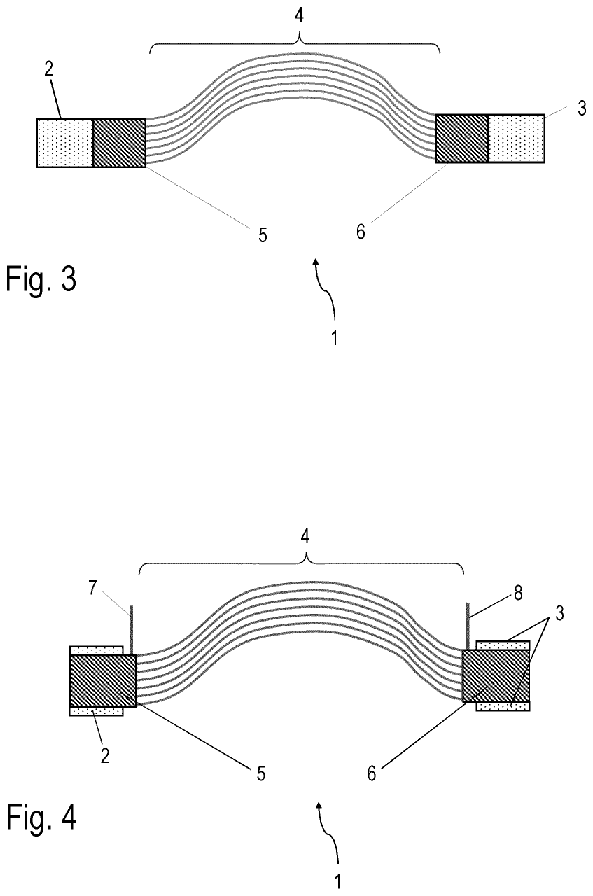

FIG. 2 shows a variation of the embodiment according to FIG. 1, so that in order to avoid repetition, reference is made to the above description, with the same reference signs being used for corresponding details.

A special feature of this embodiment is that separate mechanical connection elements 5, 6 are arranged between the connection parts 2, 3 and the resistor element 4, which is designed as a deformation element. The connection elements 5, 6 are thus connected on the one hand to the resistor element 4 and on the other hand to the connection parts 1, 2.

This design allows homogenization of the current distribution over the cross-section of the flexible resistor element 4. The mechanical and electrical connection can be made here by pressing, welding, riveting or crimping, to name just a few examples of possible connection types.

In this embodiment, the copper connection parts 2, 3 enclose the connection elements 5 and 6, respectively, so that the mechanical connection area also becomes the electrical contact region.

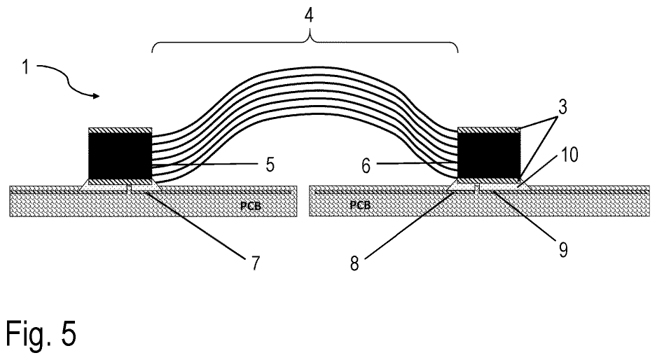

FIG. 3 shows a variation of the embodiment according to FIG. 2, so that in order to avoid repetitions, reference is made to the above description, whereby the same reference signs are used for corresponding details.

A special feature here is that the connection parts 2, 3 are attached to the outside of the connection elements 5, 6, for example by a welded joint. The mechanical connection area is therefore spatially separated from the electrical contact region.

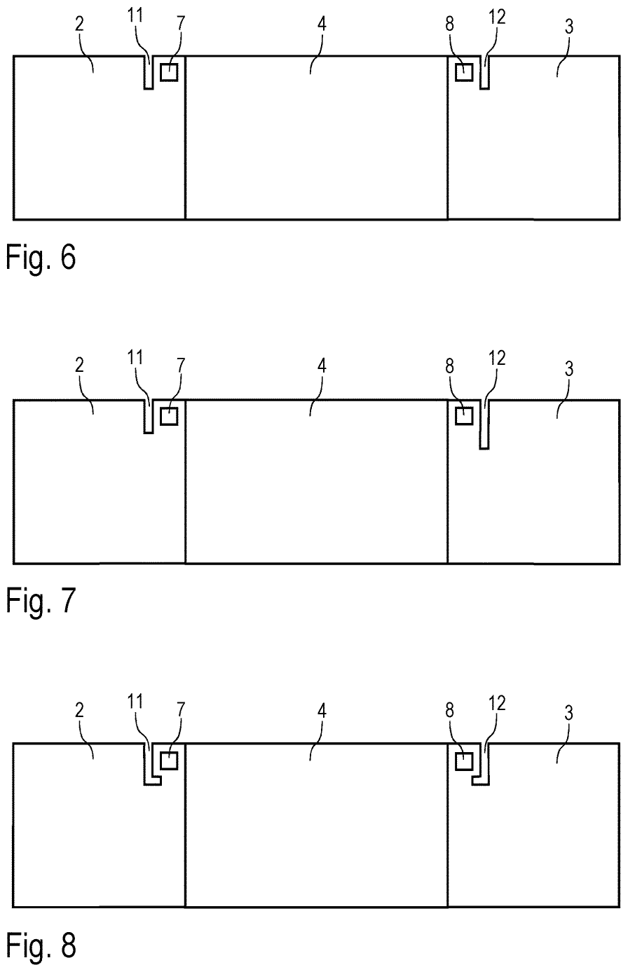

FIG. 4 shows a variation of the embodiment according to FIG. 2, so that in order to avoid repetitions, reference is again made to the above description, whereby the same reference signs are used for corresponding details.

A special feature of this embodiment is that voltage taps 7 and 8, respectively, are attached to the two connection elements 5, 6, which in this embodiment consist of pins (contact pins). At the two voltage taps 7, 8 the voltage drop across the resistor element 4 can be measured in order to measure the electric current flowing through the current measuring resistor 1 according to the four-wire technique.

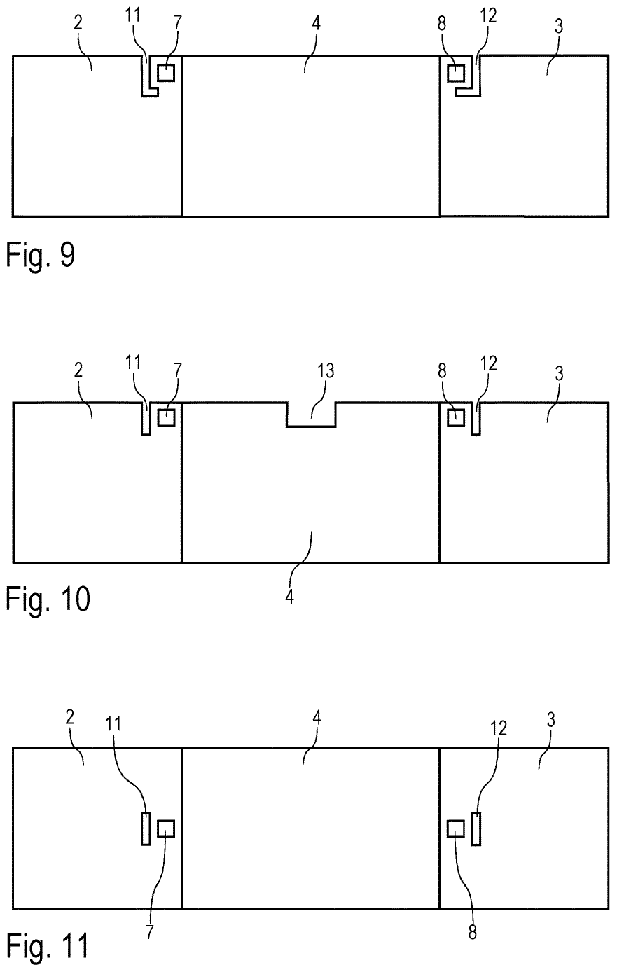

FIG. 5 shows a schematic representation of a printed circuit board arrangement according to the invention with a printed circuit board PCB (PCB: Printed Circuit Board), wherein conductor tracks 9 and voltage taps 7, 8 are located on the upper side of the printed circuit board PCB.

The current measuring resistor 1 according to the invention is arranged on the upper side of the PCB, as already described above, so that reference is made to the above description. The connection part 3 of the current measuring resistor 1 is here electrically and mechanically connected to the conductor track 9 on the printed circuit board PCB via a solder connection 10.

In addition, the connection part 3 is electrically and mechanically connected to the voltage tap 8 on the upper side of the printed circuit board PCB via a further solder connection.

On the one hand, the electric current to be measured can thus be fed from the printed circuit board PCB to the current measuring resistor 1.

On the other hand, the PCB can also measure the voltage drop across the resistor element 4 of the current measuring resistor 1 to measure the electric current flowing through the current measuring resistor 1 according to the four-wire technique.

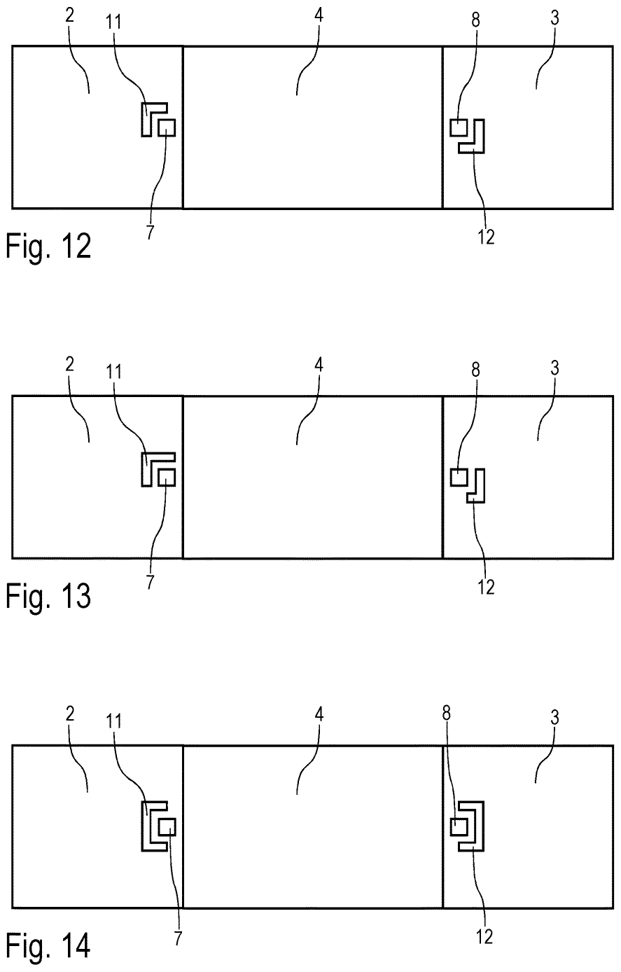

FIGS. 6-16 show various schematic representations of a current measuring resistor 1 according to the invention in different embodiments, whereby the representation again largely corresponds to the drawings described at the beginning, so that to avoid repetition reference is made to the above description, whereby the same reference signs are used for corresponding details.

Thus, the drawings show the voltage taps 7, 8 in the form of contact pads on the connection parts 2 and 3, respectively.

Furthermore, the drawings show so-called current shadows 11, 12 in the connection parts 2 and 3, respectively, the current shadows 11, 12 being incisions in the connection parts 2 and 3, respectively, which have the task of influencing the current distribution.

Here, the current shadows 11, 12 at least partially surround the voltage taps 7, 8, which are designed as contact pads.

In the embodiment according to FIG. 6, the current shadows 11, 12 extend inward from the same side edge of the current measuring resistor 1 and both have the same length.

In the embodiment according to FIG. 7, the current shadow 12 in the connection part 3 is longer than the current shadow 11 in the other connection part 2.

In the embodiment according to FIG. 8, the two current shadows 11, 12 are each L-shaped and symmetrically formed with the same size.

In the embodiment according to FIG. 9, the L-shaped current shadow 12 in the connection part 3 is longer than the current shadow 11 in the connection part 2.

The embodiment according to FIG. 10 corresponds essentially to the embodiment according to FIG. 6, but in this case there is an additional current shadow 13 in the resistor element 4, which is arranged centrally between the two connection parts 2, 3 and starts from a side edge of the current measuring resistor 1.

In the example shown in FIG. 11, the two voltage taps 7, 8 in the form of contact pads are arranged centrally between the two side edges of the current measuring resistor 1.

The two current shadows 11, 12 are also located centrally between the two side edges of the current measuring resistor 1 in the two connection parts 2, 3, whereby the two current shadows 11, 12 are designed as straight slots.

The example according to FIG. 12 corresponds in part to the example according to FIG. 11, but the two current shadows 11, 12 are L-shaped and have the same size and shape.

In the embodiment according to FIG. 13, the two current shadows 11, 12 are also L-shaped, but here the two current shadows 11, 12 have different sizes.

FIG. 14 shows a variation of the embodiments according to FIGS. 11-13, in which the two current shadows 11, 12 are U-shaped.

FIG. 15 corresponds essentially to the embodiment shown in FIG. 14, but the U-shaped current shadows 11, 12 have two legs with a different leg length.

FIG. 16 corresponds largely to the embodiment shown in FIG. 11, but here additional voltage taps 14, 15 are arranged on the connection parts 2, 3. In each of the two connection parts 2, 3 there are thus two voltage taps 7, 14 and 8, 15 respectively. This makes it possible to measure the voltage drop at different points within the current measuring resistor. This offers the advantage that inhomogeneities of the current density distribution within the current measuring resistor 1 can be eliminated.

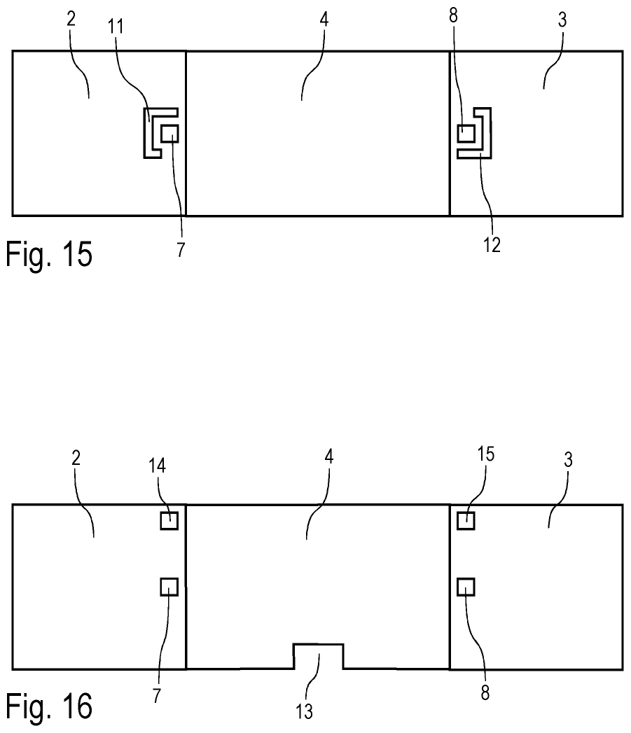

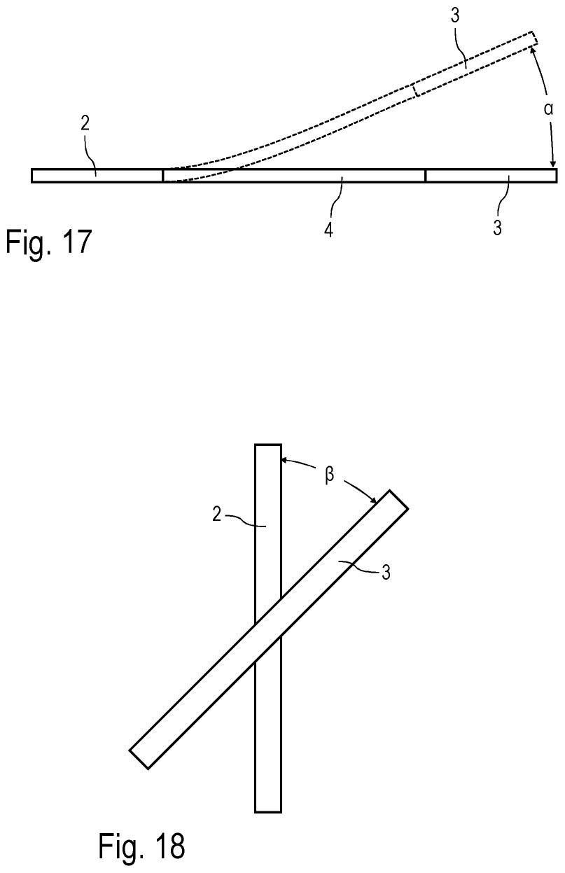

FIG. 17 shows a deformation scenario of a current measuring resistor 1 according to the invention with a bending angle α. This means that the two connection parts 2, 3 can be angled relative to each other by the bending angle α due to the flexible resistor element 4. FIG. 18 shows a schematic diagram for the deformation of a current measuring resistor 1 according to the invention, whereby the two connection parts 2, 3 can be twisted relative to each other by a twisting angle β.

The invention is not limited to the preferred embodiments described above. Rather, a large number of variants and variations are possible which also make use of the inventive concept and therefore fall within the scope of protection. In particular, the invention also claims protection for the subject matter and the features of the dependent claims independently of the claims referred to in each case and in particular also without the features of the main claim. The invention thus comprises different aspects of the invention which enjoy protection independently of each other. For example, the invention aspect of the current shadows in the current sensing resistor is also protectable independently of the flexible deformation element.

### List of Reference Signs

1 Current measuring resistor
2,3 Connection parts of the current measuring resistor
4 Resistor element of the current measuring resistor
5,6 Mechanical connection elements for connecting the resistor element with the connection parts
7,8 Voltage taps
9 Conductor track on the printed circuit board
10 Solder connection between the connection part of the current measuring resistor and the conductor path or the voltage tap of the printed circuit board
11, 12 Current shadows in the connection parts
13 Current shadow in the resistor element
14, 15 Voltage taps in the connection parts of the current sensing resistor
PCB Printed circuit board
α Bending angle between the connection parts of the current sensing resistor
β Torsion angle between the connection parts of the current sensing resistor

1-17. (canceled)

18. A current measuring resistor for measuring an electric current, comprising:
a) a first connection part comprising at least one of a conductor material and a resistor material for introducing the electric current to be measured into the current measuring resistor;
b) a second connection part comprising at least one of the conductor material and the resistor material for conducting the electric current to be measured out of the current measuring resistor;
c) a resistor element comprising a resistor material of the resistor element, the resistor element being arranged in a direction of current flow between the first connection part and the second connection part, so that the electric current to be measured flows through the resistor element during a current measurement; and
d) at least one flexible deformation element for enabling a non-destructive and reversible deformation of the current measuring resistor, the flexible deformation element being arranged between the first connection part and the second connection part in the direction of current flow, so that the electric current to be measured flows through the flexible deformation element during the current measurement, wherein the flexible deformation element is in a form of a stack comprising multiple planes arranged on top of each other.

19. The current measuring resistor according to claim 18, wherein the flexible deformation element is formed by the resistor element.

20. The current measuring resistor according to claim 18, wherein the flexible deformation element is elastically deformable.

21. The current measuring resistor according to claim 18, wherein the flexible deformation element is plastically deformable.

22. The current measuring resistor according to claim 18, wherein the flexible deformation element allows a non-destructive length change of the current measuring resistor of at least 10%.

23. The current measuring resistor according to claim 18, wherein the flexible deformation element allows a non-destructive bending of the connection parts relative to each other of at least 10°.

24. The current measuring resistor according to claim 18, wherein the flexible deformation element permits non-destructive rotation of the connection parts relative to one another by at least 10°.

25. (canceled)

26. The current measuring resistor according to claim 18, wherein the flexible deformation element is connected to the connection parts via mechanical connection elements in each case in a connecting region.

27. The current measuring resistor according to claim 26, wherein the connection parts each enclose, cover or sheathe the mechanical connection elements, so that the connecting region also forms an electrical contact region.

28. The current measuring resistor according to claim 27, wherein the connection parts are spatially separated from the mechanical connection elements so that the connecting region is separate from the electrical contact region.

29. The current measuring resistor according to claim 26, wherein the flexible deformation element is connected to at least one of the connection parts or to at least one of the mechanical connection elements by one of the following connection types:
a) a press connection;
b) a welded connection;
c) a riveted connection; and
d) a crimp connection.

30. The current measuring resistor according to claim 18, further comprising:
a) at least one first voltage tap on the first connection part and/or on the resistor element; and
b) at least one second voltage tap on the second connection part and/or on the resistor element.

31. The current measuring resistor according to claim 30, wherein:
i) the at least one first voltage tap and the at least one second voltage tap are each formed by pins;
ii) the pins are pressed into bores in the connection parts or the resistor element, welded onto the connection parts or the resistor element or soldered onto the connection parts or the resistor element;
iii) the pins consist of the conductor material of the connection parts or of the resistor material of the resistor element; and
iv) the pins are coated with a coating.

32. The current measuring resistor according to claim 18, further comprising
a) a first current shadow in a form of an incision in the first connection part for influencing the current flow in the first connection part, the first current shadow at least partially surrounding the first voltage tap, and
b) a second current shadow in a form of an incision in the second connection part for influencing the current flow in the second connection part, the second current shadow at least partially surrounding the second voltage tap.

33. The current measuring resistor according to claim 32, wherein the two current shadows in the connection parts have the same shape.

34. The current measuring resistor according to claim 32, wherein the two current shadows in the connection parts have the same length along the incision.

35. The current measuring resistor according to claim 32, wherein the two current shadows in the connection parts are L-shaped, U-shaped, C-shaped, V-shaped, straight or arc-shaped.

36. The current measuring resistor according to claim 32, wherein the two current shadows in the connection parts start from an edge of the current-measuring resistor.

37. The current measuring resistor according to claim 32, wherein the two current shadows in the connection parts have the same distance or different distances from a lateral edge of the current measuring resistor.

38. The current measuring resistor according to claim 18, wherein:
a) a current shadow in a form of an incision is arranged in the resistor element in order to influence the current flow in the resistor element;
b) the current shadow in the resistor element emanates from a lateral edge, from one or from both sides of the resistor element; and
c) the current shadow in the resistor element is arranged centrally between the connection parts.

39. The current measuring resistor according to claim 38, wherein the current shadow is arranged in all planes of a stack forming the flexible deformation element.

40. The current measuring resistor according to claim 18, wherein a trim cut is introduced into the resistor element and/or into at least one of the connection elements in order to adjust a resistance value.

41. The current measuring resistor according to claim 40, wherein the trim cut is arranged in the resistor element and/or in at least one of the connection elements as follows:
a) laterally from an edge from one side; and
b) in all planes of the stack forming the flexible deformation element.

42. The current measuring resistor according to claim 30, wherein the voltage taps are each formed by contact pads on the connection parts and/or the resistor element.

43. The current measuring resistor according to claim 30, wherein the voltage taps are formed by mating contact surfaces which are in contact with the connection parts and/or the resistor element, the mating contact surfaces optionally being located on a printed circuit board, a plug, a pin or a stamped grid.

44. The current measuring resistor according to claim 18, wherein:
a) the conductor material of the connection parts is copper;
b) the resistor material of the resistor element is selected from the group consisting of:
b1) a copper alloy;
b2) a copper-manganese-tin alloy;
b3) CuMn₁₂Ni₂;
b4) CuMn₇Sn_{2,3};
b5) a copper-manganese-nickel alloy;
b6) Cu₈₄Ni₄Mn₁₂;
b7) Cu₆₅Mn₂₅Ni₁₀;
b8) a copper-chromium alloy;
b9) a nickel alloy;
b10) NiCr;
b11) NiCr₂₀AISi;
b12) CuNi; and
b13) CuNi44;
c) the conductor material of the connection parts has a lower specific electrical resistance than the resistor material of the resistor element;
d) the resistor material of the resistor element has a specific electrical resistance smaller than 2·10⁻⁴ Ω·m;
e) the resistor material of the resistor element has a specific electrical resistance greater than 2·10⁻⁷ Ω·m; and
f) the conductor material of the connection parts has a specific electrical resistance which is smaller than 10⁻⁶ Ω·m.

45. The current measuring resistor according to claim 18, wherein:
a) the resistor material of the resistor element has a temperature coefficient of electrical resistance of less than 50 ppm/K in a temperature range T1=−20 °C to +140 °C relative to a reference temperature TRef =20 °C; and
b) the resistor material of the resistor element has a temperature coefficient of electrical resistance of less than 60 ppm/K in the temperature range T2=−40 °C to +200 °C relative to the reference temperature TRef =20 °C; and/or
c) the resistor material of the resistor element has a temperature coefficient of electrical resistance of less than 80 ppm/K in the temperature range T3=−60 °C to +200 °C relative to the reference temperature TRef=20 °C.

46. The current measuring resistor according to claim 18, wherein:
a) the connection parts are coated with a coating; and
b) the connection parts are each plate-shaped.

47. The current measuring resistor according to claim 18, wherein the current measuring resistor has an electrical resistance value of at most 10 mΩ.

48. A measuring arrangement with
a) a current measuring resistor according to claim 18, and
b) a contacting partner for the current measuring resistor, wherein at least one of the connection parts of the current measuring resistor is electrically and mechanically connected to the contacting partner.

49. The measuring arrangement according to claim 48, wherein the contacting partner is a printed circuit board, a connector, a pin or a stamped grid.
